(19) United States
(12) Patent Application Publication
(10) Pub. No.: US 2025/0382497 A1
(43) Pub. Date: Dec. 18, 2025

(54) CURABLE SILICONE COMPOSITION

(71) Applicant: DuPont Toray Specialty Materials Kabushiki Kaisha, Tokyo (JP)

(72) Inventors: Shunya TAKEUCHI, Tokyo (JP); Akihiko KOBAYASHI, Chiba (JP)

(73) Assignee: DuPont Toray Specialty Materials Kabushiki Kaisha, Tokyo (JP)

(21) Appl. No.: 18/919,828

(22) Filed: Oct. 18, 2024

(30) Foreign Application Priority Data
Jun. 18, 2024 (KR) 10-2024-0078651

(51) Int. Cl. C09D 183/04; C08G 77/12; C08G 77/20; H01L 33/56

(52) U.S. Cl. CPC C09D 183/04; C08G 77/12; C08G 77/20; H10H 20/854

(57) ABSTRACT

Disclosed is a curable silicone composition that rapidly cures at low temperature, and is capable of forming a cured product having less volume shrinkage, better transparency after being heated, and better adhesive strength. The curable silicone composition comprises: (A) an MQ resinous alkenyl group-containing organopolysiloxane having at least two alkenyl groups per molecule; (B) a resinous organohydrogenpolysiloxane having at least two silicon atom-bonded hydrogen atoms per molecule; (C) a linear organohydrogenpolysiloxane having at least two silicon atom-bonded hydrogen atoms per molecule; and (D) a curing catalyst. Relative to the total mass of the composition, the content of (B) is 5 mass % and the total content of (B) and (C) is 13 mass % or more; and the mass ratio of the (B) to (C) is 0.8 or more. Encapsulating material for semiconductors comprising the composition, and optical semiconductor devices comprising the same, are also disclosed.

### CROSS-REFERENCE TO RELATED APPLICATION

This application claims priority to and all benefits of Korean Patent Application No. 10-2024-0078651, filed Jun. 18, 2024, the content of which is incorporated herein by reference.

### FIELD OF THE DISCLOSURE

The present disclosure relates to a curable silicone composition, and more specifically relates to a curable silicone composition that is suitable for use in encapsulating materials for optical semiconductors.

### BACKGROUND

When curable silicone compositions are cured, they form cured products having excellent heat resistance, cold resistance, electrical insulation properties, weather resistance, water repellency, and transparency, and so they are used in a wide range of industrial fields. In particular, as compared to other organic materials, these cured products are less prone to discoloration and their physical properties such as durability deteriorate less, and so they are used for optical materials, and in particular are widely used as silicone encapsulating materials used in optical semiconductor devices such as light-emitting diodes (LEDs).

Japanese Unexamined Patent Publication No. 2010-174233 (Patent Document 1), for example, discloses a curable silicone composition comprising: an alkenyl group-containing dialkylpolysiloxane; a resinous alkenyl group-containing organopolysiloxane; an organopolysiloxane that has silicon atom-bonded hydrogen atoms and that has SiO4/2 units; a linear organopolysiloxane that has silicon atom-bonded hydrogen atoms; and a hydrosilylation catalyst. In examples of Patent Document 1, curable silicone rubber compositions are press-cured for 10 minutes at 120° C. and are treated for another 4 hours at 200° C.

Japanese Unexamined Patent Publication No. 2018-131583 (Patent Document 2) also discloses that a curable silicone resin composition is used as a die attach material for optical semiconductors, where the composition comprises a linear organopolysiloxane that has two or more alkenyl groups, a branched organopolysiloxane that has two or more alkenyl groups, a branched organohydrogenpolysiloxane that has two or more silicon atom-bonded hydrogen atoms, a linear organohydrogenpolysiloxane that has two or more silicon atom-bonded hydrogen atoms, and a catalyst.

Japanese Unexamined Patent Publication No. 2016-155967 (Patent Document 3) also discloses that an addition-curable silicone resin composition is used as a die attach material for optical semiconductors, where the composition comprises a linear organopolysiloxane that has two or more alkenyl groups, a branched organopolysiloxane that has two or more alkenyl groups, a branched organohydrogenpolysiloxane that has two or more silicon atom-bonded hydrogen atoms, and an addition reaction catalyst.

Japanese Unexamined Patent Publication No. 2006-328102 (Patent Document 4) furthermore discloses a silicone resin composition for molding a lens, comprising an organopolysiloxane having two or more aliphatic unsaturated bonds per molecule, a branched organohydrogenpolysiloxane having three or more silicon atom-bonded hydrogen atoms per molecule, and a platinum group metal-based catalyst. In examples of Patent Document 4, silicone resin compositions for molding a lens are molded for 90 seconds at 150° C.

International (PCT) Publication No. 2018/062009 (Patent Document 5) also discloses that an optical semiconductor is encapsulated with the cured product of a curable silicone composition that is composed of at least: a linear organopolysiloxane that has at least two silicon-bonded alkenyl groups per molecule, wherein at least 5 mol % of all silicon-bonded organic groups are aryl groups; an organopolysiloxane that consists of siloxane units represented by formula R¹³SiO1/2 (in the formula, R¹ are the same or different monovalent hydrocarbon groups) and siloxane units represented by formula SiO42, wherein the content of alkenyl groups is at least 6% by weight; an organopolysiloxane that has at least two silicon-bonded hydrogen atoms per molecule; and a hydrosilylation catalyst. Comparative Example 5 of Patent Document 5 discloses a composition that comprises, based on the total weight of polysiloxane capable of participating in the hydrosilylation reaction: 88% by weight of a linear organopolysiloxane that has at least two alkenyl groups but has no aryl groups as any of the silicon-bonded organic groups; 5.1% by weight of a vinyl group-containing organopolysiloxane MQ resin; 6.1% by weight of an organohydrogenpolysiloxane MQ resin; and 0.5% by weight of a condensation reaction product of a methylvinylsiloxane oligomer, capped at both ends of the molecular chain with silanol groups, and 3-glycidoxypropyl trimethoxysilane.

Japanese Unexamined Patent Publication No. 2016-204423 (Patent Document 6) also discloses that a light-emitting element is coated with the cured product of an addition-curable silicone composition comprising an organopolysiloxane having a network structure that has at least two alkenyl groups per molecule, a linear organopolysiloxane that has at least two alkenyl groups per molecule, a branched organohydrogenpolysiloxane that has at least two hydrosilyl groups per molecule, a linear organohydrogenpolysiloxane that has at least two hydrosilyl groups per molecule, and a hydrosilylation catalyst.

Japanese Unexamined Patent Publication No. 2015-218233 (Patent Document 7) discloses that an optical semiconductor is encapsulated with a curable organopolysiloxane composition comprising an organopolysiloxane that has alkenyl and aryl groups, an organohydrogenpolysiloxane, and an addition reaction catalyst.

Japanese Unexamined Patent Publication No. 2009-292928 (Patent Document 8) also discloses a thermally conductive silicone composition comprising a linear organopolysiloxane that has at least two alkenyl groups per molecule, an organohydrogenpolysiloxane that consists only of M units, D units, and T units, and a linear organohydrogenpolysiloxane. Comparative Example 3 of Japanese Unexamined Patent Publication No. H10-231428 (Patent Document 9) discloses a composition comprising 100 parts by weight of a dimethylpolysiloxane capped at both ends of the molecular chain with vinyldimethylsilyl groups and 1.6 parts by weight of a branched hydrogenpolysiloxane compound.

However, in order to form a cured product from a curable silicone composition that is cured via hydrosilylation reaction, the composition must sometimes be cured for a long time at an elevated temperature. For instance, examples in Patent Documents 2, 3, 5, 6, and 7 noted above disclose that curable silicone compositions are cured by being heated for at least 1 hour at 150° C. This long curing time results in lower productivity. When curable silicone compositions must be heated for a long period of time at elevated temperatures, electronic devices such as optical semiconductor elements on which the curable silicone compositions are applied may also be damaged by the heat. There is thus demand for a curable silicone composition that could be rapidly cured at a low temperature. The use of a greater amount of hydrosilylation catalyst has been entertained as a method that would allow a curable silicone composition to be rapidly cured at a low temperature. However, the use of a greater amount of hydrosilylation catalyst in curable silicone compositions may sometimes result in conspicuous discoloration of the cured product, which cannot be used in applications such as the encapsulation of optical semiconductor devices, where the cured product must be transparent.

Curable silicone compositions that are cured via hydrosilylation reaction may sometimes undergo high volume shrinkage while cured. Such volume shrinkage can lead to flexible film warpage and less precision in controlling flatness and thickness. Low viscosity in curable silicone compositions is also important for enhancing processing efficiency in processes where, for example, optical semiconductor devices are encapsulated by curable silicone compositions. Low viscosity in curable silicone compositions is also important for the self-levelling properties that are required in screen printing processes for example.

### BRIEF SUMMARY

The present embodiments provide a curable silicone composition, comprising:
(A) an MQ resinous alkenyl group-containing organopolysiloxane having at least two alkenyl groups per molecule;
(B) a resinous organohydrogenpolysiloxane having at least two silicon atom-bonded hydrogen atoms per molecule;
(C) a linear organohydrogenpolysiloxane having at least two silicon atom-bonded hydrogen atoms per molecule; and
(D) a curing catalyst,
wherein the content of the (B) resinous organohydrogenpolysiloxane is 5% by mass or more relative to the total mass of the composition,
the total content of the (B) resinous organohydrogenpolysiloxane and the (C) linear organohydrogenpolysiloxane is 13 mass % or more relative to the total mass of the composition, and
the mass ratio of the content of the (B) resinous organohydrogenpolysiloxane relative to the content of the (C) linear organohydrogenpolysiloxane is 0.8 or more.

The content of the (A) MQ resinous alkenyl group-containing organopolysiloxane is typically 30% by mass to 80% by mass.

The (B) resinous organohydrogenpolysiloxane typically has a network molecular structure.

The (B) resinous organohydrogenpolysiloxane typically comprises an MQ resinous organohydrogenpolysiloxane and/or a resinous organohydrogenpolysiloxane consisting of only M units and T units.

The mass ratio of the content of the (B) resinous organohydrogenpolysiloxane relative to the content of the (C) linear organohydrogenpolysiloxane is typically 3 or less.

The present embodiments also relate to an encapsulating material for semiconductor devices, which is formed by the curable silicone composition of the present embodiments.

The present embodiments furthermore relate to an optical semiconductor device comprising the encapsulating material for semiconductors according to the present embodiments.

### DETAILED DESCRIPTION

An object of the present embodiments is to provide a curable silicone composition capable of forming a cured product that can be rapidly cured at a low temperature, that has less volume shrinkage when cured, and that has better transparency after being heated and better adhesive strength.

As a result of extensive research to solve the above-mentioned problems, the inventors arrived at the present embodiments upon discovering that, surprisingly, the combination of an MQ resinous alkenyl group-containing organopolysiloxane with a specific organohydrogenpolysiloxane allows a cured product that has less volume shrinkage when cured and better adhesive strength to be formed by means of a rapid curing reaction at a low temperature.

The curable silicone composition according to the present embodiments can be rapidly cured at a low temperature to form a cured product that has less volume shrinkage when cured as well as better transparency after being heated and better adhesive strength.

### Curable Silicone Composition

The curable silicone composition according to the present embodiments comprises at least a curable silicone composition, comprising:
(A) an MQ resinous alkenyl group-containing organopolysiloxane having at least two alkenyl groups per molecule;
(B) a resinous organohydrogenpolysiloxane having at least two silicon atom-bonded hydrogen atoms per molecule;
(C) a linear organohydrogenpolysiloxane having at least two silicon atom-bonded hydrogen atoms per molecule; and
(D) a curing catalyst,
   and wherein:
the content of the (B) resinous organohydrogenpolysiloxane is 5% by mass or more relative to the total mass of the composition,
the total content of the (B) resinous organohydrogenpolysiloxane and the (C) linear organohydrogenpolysiloxane is 13 mass % or more relative to the total mass of the composition, and
the mass ratio of the content of the (B) resinous organohydrogenpolysiloxane relative to the content of the (C) linear organohydrogenpolysiloxane is 0.8 or more.

The components of the curable silicone composition of the present embodiments are described in detail below. (A) MQ Resinous Alkenyl Group-Containing Organopolysiloxane Having At Least Two Alkenyl Groups Per Molecule

Component (A) is an organopolysiloxane having at least two alkenyl groups per molecule. The curable silicone composition according to the present embodiments may comprise one type of (A) MQ resinous alkenyl group-containing organopolysiloxane, or may comprise two or more types of (A) MQ resinous alkenyl group-containing organopolysiloxanes.

The molecular structure of component (A) is in the form of an MQ resin. As used in the present specification, resinous means a branched or network configuration, and typically a network configuration. MQ resins mean resinous organopolysiloxanes consisting only of siloxane units represented by R₃SiO_{1/2} (M units) and siloxane units represented by SiO_{4/2} (Q units). R in the siloxane units means a silicon atom-bonded organic group.

Examples of the alkenyl groups in component (A) include C2-12 alkenyl groups such as vinyl, allyl, butenyl, pentenyl, hexenyl, heptenyl, octenyl, nonenyl, decenyl, undecenyl, and dodecenyl groups, and in some embodiments, is typically vinyl.

Examples of silicon atom-bonded groups other than alkenyl groups in component (A) include halogen-substituted or unsubstituted monovalent hydrocarbon groups other than alkenyl groups, such as: C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; C6-20 aryl groups such as phenyl, tolyl, xylyl, and naphthyl groups; C7-20 aralkyl groups such as benzyl, phenethyl, and phenylpropyl groups; and any of these groups in which some or all of the hydrogen atoms are substituted with halogen atoms such as fluorine, chlorine, and bromine atoms. The silicon atoms in component (A) may comprise a small quantity of hydroxyl groups or alkoxy groups such as methoxy or ethoxy groups, provided that the object of the present embodiments is not thereby compromised. Silicon atom-bonded groups other than alkenyl groups in component (A) are typically selected from among C1-6 alkyl groups, and methyl in particular.

The MQ resinous alkenyl group-containing organopolysiloxane of component (A) can be represented by the following average unit formula (I):

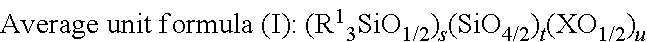

In the formula (I), R¹ indicates halogen-substituted or unsubstituted monovalent hydrocarbon groups, which may be the same or different, except at least two R¹ per molecule are alkenyl groups; 0<s1, 0<t1, 0≤u<0.4, and s+t=1.0; and u is the number of (XO) groups per silicon atom (ratio of the number of (XO) groups per silicon atom).

In formula (I) above, examples of halogen-substituted or unsubstituted monovalent hydrocarbon groups represented by R¹ include: C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; C6-20 aryl groups such as phenyl, tolyl, xylyl, and naphthyl groups; C7-20 aralkyl groups such as benzyl, phenethyl, and phenylpropyl groups; C2-12 alkenyl groups such as vinyl, allyl, butenyl, pentenyl, hexenyl, heptenyl, octenyl, nonenyl, decenyl, undecenyl, and dodecenyl groups; and any of these groups in which some or all of the hydrogen atoms are substituted with halogen atoms such as fluorine, chlorine, and bromine atoms. R¹ may also be a hydroxyl group or an alkoxy group such as methoxy or ethoxy, in small amounts, provided that the object of the present embodiments is not thereby compromised. R¹ is typically selected from C1-6 alkyl groups, and methyl in particular, or C2-6 alkenyl groups, and vinyl in particular.

In formula (I) above, X is a hydrogen atom or an alkyl group. Preferred examples of alkyl groups represented by X include C1-3 alkyl groups, specifically, methyl, ethyl, and propyl groups. In some embodiments, X is a hydrogen atom.

In formula (I), s is typically in the range of 0.2≤s≤0.8, alternatively in the range of 0.3≤s≤0.7, and even alternatively in the range of 0.4 ≤s≤0.6. In formula (I) above, t is typically in the range of 0.2≤t≤0.8, alternatively in the range of 0.3≤t≤0.7, and in particular in the range of 0.4≤t≤0.6. In formula (1) above, u is typically in the range of 0≤u≤0.15, alternatively in the range of 0≤u≤0.1, and in particular in the range of 0≤u≤0.05.

The content of the alkenyl groups in all of the silicon atom-bonded organic groups of the MQ resinous alkenyl group-containing organopolysiloxane of component (A) is not particularly limited, but may be, for example, 1 mol % or more, alternatively 2 mol % or more, and alternatively 3 mol % or more of the total of the silicon atom-bonded organic groups, and can be 20 mol % or less, alternatively 15 mol %, and alternatively 10 mol % or less of the total of the silicon atom-bonded organic groups. The alkenyl group content can be determined by means of analysis such as Fourier transform infrared spectrophotometry (FT-IR) or nuclear magnetic resonance (NMR), or by means of a titration method described below. As used in the present specification, numerical ranges can be established, as appropriate, by combining any upper and lower limits of the numerical range.

A method for determining the amount of alkenyl groups in the components by means of a titration method will be described. The alkenyl group content in the organopolysiloxane components can be accurately quantified by means of a titration method generally known as the Wijs method. The principles are described below.

Firstly, the alkenyl groups in the organopolysiloxane starting material and iodine monochloride are subjected to an addition reaction as shown in formula (1). Next, according to the reaction shown in formula (2), an excess amount of iodine monochloride is reacted with potassium iodide, thereby freeing iodine. The freed iodine is subjected to titration with a sodium thiosulfate solution.

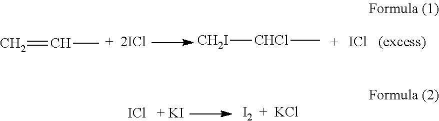

The amount of alkenyl groups in the component can be quantified from the difference between the amount of sodium thiosulfate required for titration and the titration amount of a separately prepared blank solution.

The content of the aryl groups in all of the silicon atom-bonded organic groups of the MQ resinous alkenyl group-containing organopolysiloxane of component (A) is not particularly limited, but can be, for example, 20 mol % or less, alternatively 10 mol %, and alternatively 5 mol % or less of the total of the silicon atom-bonded organic groups. In one embodiment of the present embodiments, the MQ resinous alkenyl group-containing organopolysiloxane of component (A) contains no aryl groups as silicon atom-bonded organic groups.

The aryl group content can, for example, be determined by analysis such as Fourier transform infrared spectrophotometry (FT-IR) or nuclear magnetic resonance (NMR).

The viscosity of the (A) MQ resinous alkenyl group-containing organopolysiloxane is not particularly limited. For example, component (A) is typically a solid at 25° C. For example, the viscosity at 25° C. is in the range of 1 to 200,000 mPa·s, and alternatively in the range of 5 to 100,000 mPa·s. As used in the present specification, the viscosity of the organopolysiloxane component can be determined using a rotary viscometer per JIS K 7117-1.

The number-average molecular weight of the (A) MQ resinous alkenyl group-containing organopolysiloxane may be, for example, but is not particularly limited to, 1,000 or more, and alternatively 1,500 or more, and can be 200,000 or less, alternatively 150,000 or less, and even alternatively 100,000 or less. As used in the present specification, the number-average molecular weight (Mn) and weight-average molecular weight (Mw) are values calculated on the basis of standard polystyrene, as determined by gel permeation chromatography (GPC).

The number of siloxane units (SiO_{x/2}) in the (A) MQ resinous alkenyl group-containing organopolysiloxane may be, for example, but is not particularly limited to, 5 to 2,000, and alternatively 10 to 1,000.

The content of the (A) MQ resinous alkenyl group-containing organopolysiloxane is usually, but is not particularly limited to, 30% by mass or more, alternatively 40% by mass or more, and even alternatively 50% by mass or more, based on the total mass of the curable silicone composition of the present embodiments. The content of component (A) is also usually 80% by mass or less, alternatively 70% by mass or less, and alternatively 60% by mass or less, based on the total mass of the curable silicone composition of the present embodiments.

### (B) Resinous Organohydrogenpolysiloxane Having at Least Two Silicon Atom-Bonded Hydrogen Atoms Per Molecule

Component (B) is a resinous organohydrogenpolysiloxane which acts as a crosslinking agent for the curable silicone composition by way of a hydrosilylation curing reaction, and has at least two silicon atom-bonded hydrogen atoms per molecule. The curable silicone composition according to the present embodiments may comprise one type of a (B) resinous organohydrogenpolysiloxane, or may comprise two or more types of (B) resinous organohydrogenpolysiloxanes.

Examples of silicon atom-bonded groups other than silicon atom-bonded hydrogen atoms in component (B) include halogen-substituted or unsubstituted monovalent hydrocarbon groups other than alkenyl groups, for example, C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; C6-20 aryl groups such as phenyl, tolyl, xylyl, and naphthyl groups; C7-20 aralkyl groups such as benzyl, phenethyl, and phenylpropyl groups; and any of these groups in which some or all of the hydrogen atoms are substituted with halogen atoms such as fluorine, chlorine, and bromine atoms. The silicon atoms in component (B) may also have a small amount of hydroxyl groups or alkoxy groups such as methoxy or ethoxy groups, provided that the object of the present embodiments is not thereby compromised. The silicon atom-bonded groups other than silicon atom-bonded hydrogen atoms in component (B) can be selected from C1-6 alkyl groups, and methyl in particular.

In one embodiment of the present embodiments, the resinous organohydrogenpolysiloxane of component (B) can be represented by the following average unit formula (II):

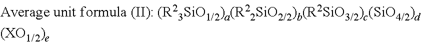

In formula (II), R² are hydrogen atoms, or the same or different halogen-substituted or unsubstituted monovalent hydrocarbon groups other than alkenyl groups, except at least two R² per molecule are hydrogen atoms; 0≤a<1, 0≤b<1, 0≤c<0.9, 0≤d<0.7, and 0≤e<0.4; a+b+c+d=1.0; and c+d>0. The symbol e represents the number of (XO) groups per silicon atom (ratio of the number of (XO) groups per silicon atom).

Examples of the halogen-substituted or unsubstituted monovalent hydrocarbon groups other than alkenyl groups of R² in formula (II) include C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; C6-20 aryl groups such as phenyl, tolyl, xylyl, and naphthyl groups; C7-20 aralkyl groups such as benzyl, phenethyl, and phenylpropyl groups; and any of these groups in which some or all of the hydrogen atoms are substituted with halogen atoms such as fluorine, chlorine, and bromine atoms. R² may also be a hydroxyl group or an alkoxy group such as methoxy or ethoxy, in small amounts, provided that the object of the present embodiments is not thereby compromised. R² is typically selected from hydrogen atom and C1-6 alkyl groups, and methyl in particular.

X in Formula (II) above is a hydrogen atom or an alkyl group. Preferred examples of alkyl groups represented by X include C1-3 alkyl groups, specifically, methyl, ethyl, and propyl groups. In some embodiments, X is a hydrogen atom.

In formula (II) above, a is typically in the range of 0.1≤a≤0.9, alternatively in the range of 0.3≤a≤0.8, and even alternatively in the range of 0.5≤a≤0.7. In formula (II) above, b is typically in the range of 0≤b≤0.5, alternatively in the range of 0≤b≤0.3, and particularly in the range of 0≤b≤0.1. In formula (I) above, c is typically in the range of 0.1≤c≤0.7, alternatively in the range of 0.2≤c≤0.6, and particularly in the range of 0.3≤c≤0.5. In formula (II) above, d is typically in the range of 0≤d≤0.7, alternatively in the range of 0≤d≤0.6, and particularly in the range of 0≤d≤0.5. In formula (II) above, e is typically in the range of 0≤e≤0.15, alternatively in the range of 0≤e≤0.1, and particularly in the range of 0≤e≤0.05.

Preferred embodiments of the present disclosure may or may not, and preferably do not, include siloxane units represented by R₂SiO_{1/2} (D units). In specific embodiments, the resinous organohydrogenpolysiloxane of component (B) is free from siloxane units represented by R₂SiO_{1/2} (D units).

In a preferred embodiment of the present disclosure, the resinous organohydrogenpolysiloxane of component (B) contains a silicon atom-bonded hydrogen atom at a molecular terminal. The resinous organohydrogenpolysiloxane of component (B) typically has a silicon atom-bonded hydrogen atom in the M unit, and may or may not, and preferably does not, include a silicon atom-bonded hydrogen atom in molecular-chain side chains (specifically, D units and T units).

In a preferred embodiment of the present disclosure, the resinous organohydrogenpolysiloxane of component (B) may or may not contain an aryl group in the silicon atom-bonded organic groups. Examples of aryl groups include C6-20 aryl groups, such as phenyl, tolyl, xylyl, and naphthyl groups, and phenyl in particular.

When the resinous organohydrogenpolysiloxane of component (B) comprises aryl groups, the content (mol % of aryl groups in all of the silicon atom-bonded functional groups of the resinous organohydrogenpolysiloxane) can be designed as desired, but is normally 5 mol % or more, alternatively 10 mol % or more, and alternatively 15 mol % or more, and can be 50 mol % or less, alternatively 40 mol % or less, and alternatively 30 mol % or less.

In another embodiment of the present disclosure, the resinous organohydrogenpolysiloxane of component (B) does not contain an aryl group in the silicon atom-bonded organic groups, or contains no more than 15 mol % and at least 10 mol % or 5 mol % relative to all silicon atom-bonded functional groups.

In one embodiment of the present disclosure, component (B) comprises a resinous organohydrogenpolysiloxane and an MQ resinous organohydrogenpolysiloxane. The MQ resinous organohydrogenpolysiloxane can be represented by the following average unit formula (II-a):

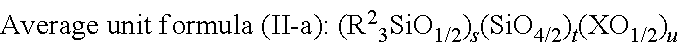

In the formula, R² indicates hydrogen atoms, or halogen-substituted or unsubstituted monovalent hydrocarbon groups other than alkenyl groups, which may be the same or different, except at least two R² per molecule are hydrogen atoms; 0<s<1, 0<t<1, O≤u<0.4, and s+t=1.0; and u is the number of (XO) groups per silicon atom (ratio of the number of (XO) groups per silicon atom).

R² and X in formula (II-a) above are as defined in formula (II) above, and the same definitions are applicable.

In formula (II-a), s is typically in the range of 0.3≤s≤0.9, alternatively in the range of 0.4≤s≤0.8, and even alternatively in the range of 0.5≤s≤0.7. In formula (II-a) above, t is typically in the range of 0.1≤t≤0.7, alternatively in the range of 0.2≤t≤0.6, and in particular in the range of 0.33≤t≤0.5. In formula (II-a) above, u is typically in the range of 0≤u≤0.15, alternatively in the range of 0≤u≤0.1, and in particular in the range of 0≤u≤0.05.

In one embodiment of the present disclosure, the MQ resinous organohydrogenpolysiloxane serving as component (B) does not contain an aryl group in the silicon atom-bonded organic groups, or contains no more than 15 mol % and at least 10 mol % or 5 mol % relative to all silicon atom-bonded functional groups.

In one embodiment of the present disclosure, component (B) comprises a resinous organohydrogenpolysiloxane, and a resinous organohydrogenpolysiloxane consisting of only M units and T units. The resinous organohydrogenpolysiloxane consisting of only M units and T units can be represented by the following average unit formula (II-b):

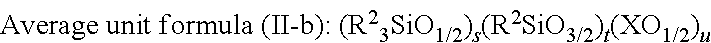

In the formula (II), R² indicates hydrogen atoms, or halogen-substituted or unsubstituted monovalent hydrocarbon groups other than alkenyl groups, which may be the same or different, except at least two R² per molecule are hydrogen atoms; 0≤s≤1, 0≤t≤1, O≤u≤0.4, and s+t=1.0; and u is the number of (XO) groups per silicon atom (ratio of the number of (XO) groups per silicon atom).

R² and X in formula (II-b) above are as defined in formula (II) above.

In formula (II-b), s is typically in the range of 0.3≤s≤0.9, alternatively in the range of 0.45≤s≤0.8, and even alternatively in the range of 0.5≤s≤0.7. In formula (II-b) above, t is typically in the range of 0.1≤t≤0.7, alternatively in the range of 0.2≤t≤0.6, and in particular in the range of 0.3≤t≤0.5. In formula (II-b) above, u is typically in the range of 0≤u≤0.15, alternatively in the range of 0≤u≤0.1, and in particular in the range of 0≤u≤0.05.

In one embodiment of the present disclosure, the resinous organohydrogenpolysiloxane consisting of only M units and T units serving as component (B) may comprise an aryl group in the silicon atom-bonded organic groups, where the content (mol % of aryl groups in all of the silicon atom-bonded functional groups of the resinous organohydrogenpolysiloxane) can be designed as desired, but is normally 5 mol % or more, alternatively 10 mol % or more, and alternatively 15 mol % or more, and can be 50 mol % or less, alternatively 40 mol % or less, and alternatively 30 mol % or less.

The viscosity of the resinous organohydrogenpolysiloxane of component (B) may be, for example, but is not particularly limited to, the range of 10 mPa to 1,000 mPa at 25° C. In the present specification, the viscosity of the organopolysiloxane component can be determined at 25° C. using a rotary viscometer according to JIS K7117-1.

In one embodiment of the present disclosure, the number-average molecular weight (Mn) of the resinous organohydrogenpolysiloxane of component (B) is typically in the range of 500 to 3,000, and alternatively in the range of 600 to 2,000. In one embodiment of the present disclosure, the weight-average molecular weight (Mw) of the resinous organohydrogenpolysiloxane of component (B) is typically in the range of 500 to 3,000, and alternatively in the range of 600 to 2,000.

The content of the resinous organohydrogenpolysiloxane of component (B) is 5% by mass or more based on the total mass of the curable silicone composition of the present disclosure. The content of component (B) is also usually 30% by mass or less, alternatively 20% by mass or less, and alternatively 15% by mass or less, based on the total mass of the curable silicone composition of the present disclosure.

### (C) Linear Organohydrogenpolysiloxane Having at Least Two Silicon Atom-Bonded Hydrogen Atoms Per Molecule

Component (C) is a linear organohydrogenpolysiloxane which acts as a crosslinking agent for the curable silicone composition by way of a hydrosilylation curing reaction in the same manner as component (B), and has at least two silicon atom-bonded hydrogen atoms per molecule. The curable silicone composition according to the present disclosure may comprise one type of a (C) linear organohydrogenpolysiloxane, or may comprise two or more types of (C) linear organohydrogenpolysiloxanes.

Examples of silicon atom-bonded groups other than silicon atom-bonded hydrogen atoms in component (C) include halogen-substituted or unsubstituted monovalent hydrocarbon groups other than alkenyl groups, for example, C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; C6-20 aryl groups such as phenyl, tolyl, xylyl, and naphthyl groups; C7-20 aralkyl groups such as benzyl, phenethyl, and phenylpropyl groups; and any of these groups in which some or all of the hydrogen atoms are substituted with halogen atoms such as fluorine, chlorine, and bromine atoms. The silicon atoms in component (C) may also have a small amount of hydroxyl groups or alkoxy groups such as methoxy or ethoxy groups, provided that the object of the present disclosure is not thereby compromised. The silicon atom-bonded groups other than silicon atom-bonded hydrogen atoms in component (C) can be selected from C1-6 alkyl groups, and methyl in particular.

In one embodiment of the present disclosure, component (C) can be represented by:

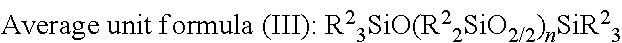

In formula (II), R² are hydrogen atoms, or halogen-substituted or unsubstituted monovalent hydrocarbon groups other than alkenyl groups, which may be the same or different, except at least two R2 per molecule are hydrogen atoms, and nis 1 to 200.

The halogen-substituted or unsubstituted monovalent hydrocarbon groups other than alkenyl groups represented by R² in formula (II) above are as defined in formula (I) above, and the same definitions are applicable.

In formula (III), n is typically 1 to 100, and alternatively 1 to 50. In another embodiment, the number of siloxane units in component (C) is usually in the range of 3 to 200, alternatively 3 to 100, and alternatively 3 to 50.

In a preferred embodiment of the present disclosure, the linear organohydrogenpolysiloxane of component

(C) has silicon atom-bonded hydrogen atoms at both terminals of the molecular chain. The linear organohydrogenpolysiloxane of component (C) has a silicon atom-bonded hydrogen atom in the M unit, and may or may not, but preferably does not, have a silicon atom-bonded hydrogen atom in the D unit.

In one embodiment, component (C) may or may not include an aryl group in the silicon atom-bonded organic groups. Examples of aryl groups include C6-20 aryl groups, such as phenyl, tolyl, xylyl, and naphthyl groups, and phenyl in particular.

When the linear organohydrogenpolysiloxane of component (C) comprises aryl groups, the content (mol % of aryl groups in all of the silicon atom-bonded functional groups of the linear organohydrogenpolysiloxane) can be designed as desired, but is normally 5 mol % or more, alternatively 10 mol % or more, and alternatively 15 mol % or more, and can be 50 mol % or less, alternatively 40 mol % or less, and alternatively 30 mol % or less.

The content of component (C) is not particularly limited, but is typically 1% by mass or more, alternatively 3% by mass or more, and even alternatively 5% by mass or more, based on the total mass of the curable silicone composition. The content of component (C) is also usually 20% by mass or less, alternatively 15% by mass or less, and alternatively 10% by mass or less, based on the total mass of the curable silicone composition.

In the present disclosure, the total content of the (B) resinous organohydrogenpolysiloxane and the (C) linear organohydrogenpolysiloxane is 13 mass % or more based on the total mass of the curable silicone composition of the present disclosure. The mass ratio of the content of the (B) resinous organohydrogenpolysiloxane relative to the content of the (C) linear organohydrogenpolysiloxane is also 0.8 or more, and alternatively 0.85 or more. The mass ratio of the content of the (B) resinous organohydrogenpolysiloxane relative to the content of the (C) linear organohydrogenpolysiloxane is also usually 3 or less, alternatively 2.5 or less, and alternatively 2 or less.

In one embodiment of the present disclosure, the components can be included such that the ratio (H/A1) of silicon atom-bonded hydrogen atoms relative to the silicon atom-bonded alkenyl groups in the organopolysiloxane components of the present disclosure is 0.7 mol or more, alternatively 0.8 mol or more, alternatively 0.9 mol or more, and in particular 0.95 mol or more silicon atom-bonded hydrogen atoms per mol silicon atom-bonded alkenyl groups in the curable silicone composition, and can also be included such that, for example, the ratio is 3 mols or less, alternatively 2 mols or less, alternatively 1.7 mols or less, and alternatively 1.6 mols or less silicon atom-bonded hydrogen atoms per mol of silicon atom-bonded alkenyl groups in the curable silicone composition.

### (D) A Curing Catalyst

The curing catalyst of component (D) is a hydrosilylation reaction curing catalyst, which is a catalyst for promoting curing of the curable silicone composition of the present embodiments. Examples of component (E) include platinum-based catalysts such as chloroplatinic acid, alcohol solutions of chloroplatinic acid, platinum-olefin complexes, platinum-and-1,3-divinyl-1,1,3,3-tetramethyldisiloxane complexes, and platinum-supporting powders; palladium-based catalysts such as tetrakis(triphenylphosphine)palladium, and mixtures of triphenylphosphine and palladium black; and rhodium-based catalysts; but platinum-based catalysts are particularly preferred.

Component (D) is blended in a catalytic amount; more specifically, when a platinum-based catalyst is used as component (D), the amount of platinum atoms is typically 0.01 ppm or more, alternatively 0.1 ppm or more, and even alternatively 1 ppm or more relative to the total mass of the curable silicone composition of the present embodiments, and can also be 20 ppm or less, alternatively 15 ppm or less, and even alternatively 10 ppm or less relative to the total mass of the curable silicone composition of the present embodiments.

### Other Organopolysiloxane Components

The curable silicone composition according to the present embodiments may also include organopolysiloxane components other than components (A) through (C). Examples of such other organopolysiloxane components include linear alkenyl group-containing organopolysiloxanes, organosiloxane oligomers having at least one epoxy group, and cerium-containing organopolysiloxanes.

The curable silicone composition according to the present embodiments may contain one or more linear alkenyl group-containing organopolysiloxanes. The linear alkenyl group-containing organopolysiloxanes can be represented by the following formula (IV):

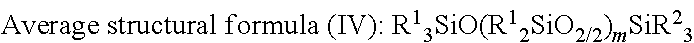

In formula (IV), R¹ are halogen-substituted or unsubstituted monovalent hydrocarbon groups, which may be the same or different, except at least two R¹ per molecule are alkenyl groups, and m is an integer from 1-500.

In formula (IV) above, the same halogen-substituted or unsubstituted monovalent hydrocarbon groups of R¹ as in formula (I) above can be used.

In formula (IV) above, m is typically 5 to 300, alternatively 10 to 250, and even alternatively 20 to 200.

Examples of such linear alkenyl group-containing organopolysiloxanes include: dimethylpolysiloxane capped at both ends of the molecular chain with dimethylvinylsiloxy groups, dimethylpolysiloxane capped at both ends of the molecular chain with diphenylvinylsiloxy groups, dimethylsiloxane-methylphenylsiloxane copolymers capped at both ends of the molecular chain with dimethylvinylsiloxy groups, dimethylsiloxane-diphenylsiloxane copolymers capped at both ends of the molecular chain with dimethylvinylsiloxy groups, dimethylsiloxane-methylphenylsiloxane copolymers capped at both ends of the molecular chain with diphenylvinylsiloxy groups, dimethylsiloxane-methylvinylsiloxane copolymers capped at both ends of the molecular chain with dimethylvinylsiloxy groups, dimethylsiloxane-methylphenylsiloxane-methylvinylsiloxane copolymers capped at both ends of the molecular chain with dimethylvinylsiloxy groups, dimethylsiloxane-diphenylsiloxane-methylvinylsiloxane copolymers capped at both ends of the molecular chain with dimethylvinylsiloxy groups, methylvinylpolysiloxane capped at both ends of the molecular chain with trimethylsiloxy groups, methylvinylsiloxane-methylphenylsiloxane copolymers capped at both ends of the molecular chain with trimethylsiloxy groups, methylvinylsiloxane-diphenylsiloxane copolymers capped at both ends of the molecular chain with trimethylsiloxy groups, and dimethylsiloxane-methylvinylsiloxane copolymers capped at both ends of the molecular chain with trimethylsiloxy groups.

In a preferred embodiment of the present disclosure, the linear alkenyl group-containing organopolysiloxane can be a linear organopolysiloxane that has alkenyl groups at both molecular terminals, where both ends of the molecular chain are capped with alkenyl groups. The linear organopolysiloxane may or may not, but preferably does not, include an alkenyl group in a molecular-chain side chain (specifically, D unit).

The alkenyl group content in the linear alkenyl-groups containing organopolysiloxane (mol % of alkenyl groups in all silicon atom-bonded functional groups of the linear organopolysiloxane) can be designed as desired, but may normally be 1 mol % or more, alternatively 2 mol % or more, and alternatively 3 mol % or more, and can also be 20 mol % or less, alternatively 15 mol % or less, and alternatively 10 mol % or less. The alkenyl group content can be determined by analysis such as Fourier transform infrared spectrophotometry (FT-IR), nuclear magnetic resonance (NMR), and the titration methods noted above.

In one embodiment, the linear alkenyl group-containing organopolysiloxane may or may not contain aryl groups in the silicon atom-bonded organic groups. Examples of aryl groups include C6-20 aryl groups, such as phenyl, tolyl, xylyl, and naphthyl groups, and phenyl in particular. When the linear alkenyl group-containing organopolysiloxane contains aryl groups, the content (mol % of aryl groups in all silicon atom-bonded functional groups of the linear organopolysiloxane) can be designed as desired, but is normally 5 mol % or more, alternatively 10 mol % or more, and alternatively 15 mol % or more, and can also be 50 mol % or less, alternatively 40 mol % or less, and alternatively 30 mol % or less.

When the curable silicone composition of the present embodiments contains a linear alkenyl-group containing organopolysiloxane, the content is not particularly limited but is usually 5% by mass or more, alternatively 10% by mass or more, and even alternatively 20% by mass or more, based on the total mass of the curable silicone composition of the present embodiments. The content of the linear alkenyl group-containing organopolysiloxane is usually 50% by mass or less, alternatively 40% by mass or less, and even alternatively 35% by mass or less, based on the total mass of the curable silicone composition of the present embodiments.

The curable silicone composition according to the present embodiments may comprise one type of organosiloxane oligomer having at least one epoxy group, or may comprise combinations of two or more types of organosiloxane oligomers having at least one epoxy group.

The epoxy group-containing organosiloxane oligomer can contain 2 to 20 siloxane units, alternatively 3 to 18 siloxane units, and alternatively 3 to 15 siloxane units.

Examples of the molecular structure of the organosiloxane oligomer(s) having at least one epoxy group include linear, linear with some branching, branched, resinous, cyclic, and three-dimensional network structures. In one embodiment, the epoxy group-containing organosiloxane oligomer is a resinous epoxy group-containing organosiloxane oligomer.

The epoxy group-containing organosiloxane oligomer has at least one epoxy group. Examples of epoxy groups in epoxy group-containing organosiloxane oligomers include: glycidoxy alkyl groups such as 2-glycidoxyethyl, 3-glycidoxypropyl, and 4-glycidoxybutyl groups; epoxycycloalkyl alkyl groups such as 2-(3,4-epoxycyclohexyl)-ethyl and 3-(3,4-epoxycylohexyl)-propyl groups; and epoxyalkyl groups such as 3,4 epoxybutyl and 7,8-epoxyoctyl groups.

Examples of silicon atom-bonded organic groups other than epoxy groups in epoxy group-containing organosiloxane oligomers include: C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; C2-12 alkenyl groups such as vinyl, allyl, butenyl, pentenyl, hexenyl, heptenyl, octenyl, nonenyl, decenyl, undecenyl, and dodecenyl groups, and in some embodiments is vinyl; C6-12 aryl groups such as phenyl, tolyl, xylyl, and naphthyl groups; C7-12 aralkyl groups such as benzyl, phenethyl, and phenylpropyl groups; and any of these groups in which some or all of the hydrogen atoms are substituted with halogen atoms such as fluorine, chlorine, and bromine atoms. Silicon-bonded organic groups other than epoxy groups include C1-12 alkyl groups, and methyl in particular, or C2-12 alkenyl groups, and vinyl in particular. The epoxy group-containing organosiloxane oligomer may contain a thiol group.

In a preferred embodiment of the disclosure, the epoxy group-containing organosiloxane oligomer contains at least one epoxy group and at least one alkenyl group, such as a vinyl group.

In one embodiment of the present disclosure, the epoxy group-containing organosiloxane oligomer is a resinous epoxy group-containing organosiloxane oligomer that can be represented by the following average unit formula (V):

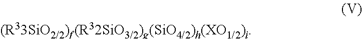

In the formula (V), R³ are each independently a halogen-substituted or unsubstituted monovalent hydrocarbon group, except at least one R³ is an epoxy group-containing organic group; X is a hydrogen atom or alkyl group, where the numbers satisfy 0≤f<1, 0≤g<1,0≤h<0.95, 0≤i<0.4, f+g+h=1.0, and g+h>0. The symbol i represents the number of (XO) groups per silicon atom (ratio of the number of (XO) groups per silicon atom).

In formula (V) above, examples of halogen-substituted or unsubstituted monovalent hydrocarbon groups represented by R³ include the above-mentioned alkenyl groups, epoxy group-containing organic groups, and monovalent hydrocarbon groups other than these. Preferred examples of alkyl groups represented by X include C1-3 alkyl groups, specifically, methyl, ethyl, and propyl groups.

In formula (V) above, f is typically in the range of 0.1≤f≤0.9, alternatively in the range of 0.3≤f≤0.8, and even alternatively in the range of 0.5≤f≤0.7. In formula (V) above, g is typically in the range of 0.05≤g≤0.6, alternatively in the range of 0.1≤g≤0.5, and in particular in the range of 0.15≤g≤0.4. In formula (V) above, h is typically in the range of 0≤h≤0.5, alternatively in the range of 0≤h≤0.3, and particularly in the range of 0≤h≤0.1. In formula (V) above, i is typically in the range of 0≤i≤0.2, alternatively in the range of 0≤i≤0.1, and particularly in the range of 0≤i≤0.05.

In one embodiment of the present disclosure, the resinous epoxy group-containing organosiloxane oligomer contains no siloxane units represented by SiO_{1/2} (M units). In another embodiment of the present disclosure, g in formula (V) above is greater than 0; specifically, the resinous epoxy group-containing organosiloxane oligomer contains a siloxane unit represented by SiO_{3/2} (T unit). The resinous epoxy group-containing organosiloxane oligomer may or may not, and preferably does not, include siloxane units represented by SiO_{4/2} (Q units). In another embodiment of the present disclosure, i in formula (V) above is greater than 0; specifically, the resinous epoxy group-containing organosiloxane oligomer has at least one silicon atom-bonded —OX group. In one embodiment of the present disclosure, the resinous epoxy group-containing organosiloxane oligomer consists only of D units and T units.

In another embodiment of the disclosure, the epoxy group-containing organosiloxane oligomer is a condensation reaction product of at least one organosilane compound containing at least one epoxy group. Such a condensation reaction product may be derived from one type of organosilane compound, or may be derived from two or more types of organosilane compounds. In other words, the structure of the epoxy group-containing organosiloxane oligomer contains units that are derived from an organosilane compound containing at least one epoxy group.

The condensation reaction can be a hydrolysis condensation reaction. The epoxy group-containing organosiloxane oligomer may thus be a hydrolysis condensation reaction product.

The degree of condensation of the condensation reaction can be, but is not particularly limited to, 2 to 20, alternatively 3 to 15, and alternatively 3 to 10 siloxane units.

The organosilane compound containing at least one epoxy group can be a monosilane compound. Examples of epoxy groups contained in such organosilane compounds include the same epoxy groups noted above.

In one embodiment of the present disclosure, the organosilane compound can be represented by the formula: R_{(4-b)}SiX_{b}. In this formula, R indicates the same or different organic functional groups having at least one e oxy group, X indicates the same or different alkoxy groups, such as methoxy, ethoxy, and propoxy groups; oxime groups, such as acetoxime or methylethylketoxime groups; amino groups, such as dimethylamino or diethylamino groups; amide groups, such as N-methylacetamide; aminooxy groups, such as diethylaminooxy; or alkenyloxy groups, such as isopropenyloxy; and bis 1, 2, or 3, alternatively 2 or 3, and alternatively 3.

In the formula R_{(4b)}SiX_{b} representing the organosilane compound above, X is typically selected from alkoxy groups, and typically C₁-C₆ alkoxy groups, such as methoxy, ethoxy, and propoxy groups.

The organosilane compound may be a silane coupling agent. Examples of such organosilane compounds include 3-glycidoxypropyltrimethoxysilane, 3-glycidoxypropyltriethoxysilane, 3-glycidoxypropylmethyldimethoxysilane, 3-glycidoxypropylmethyldiethoxysilane, glycidyloxypropyl(dimethoxy)methylsilane, glycidyloxypropyl(trimethoxy)silane, and 2-(3,4-epoxy)cyclohexyl)ethyltrimethoxysilane.

In a specific embodiment of the present disclosure, the epoxy group-containing organosiloxane oligomer is a 2 to 20 glycidoxypropyltrimethoxysilane, 3-glycidoxypropyltriethoxysilane, 3-glycidoxypropylmethyldimethoxysilane, 3-glycidoxypropylmethyldiethoxysilane, glycidyloxypropyl(dimethoxy)methylsilane, glycidyloxypropyl(trimethoxy)silane, 2-(3,4 epoxy)cyclohexyl)ethyltrimethoxysilane, glycidyloxypropyl(trimethoxy)silane, or condensation reaction product of any combination thereof, especially a condensation reaction product of four glycidyloxypropyl(trimethoxy)silanes.

In yet another embodiment of the present disclosure, the epoxy group-containing organosiloxane oligomer is a condensation reaction product of: at least one organosilane compound containing at least one epoxy group; and at least one organosilane compound containing at least one organic functional group other than an epoxy group, or an oligomer thereof. In one embodiment, the epoxy group-containing organosiloxane oligomer is a condensation reaction product of: at least one organosilane compound containing at least one epoxy group; and at least one organosilane compound containing at least one ethylenically unsaturated group such as an alkenyl group, for example, a vinyl group, or an oligomer thereof.

In yet another embodiment of the present disclosure, the epoxy group-containing organosiloxane oligomer is a condensation reaction product of: a vinyl group-containing organosiloxane oligomer capped at both ends of the molecule with silanol groups; and 3-glycidoxypropyltrimethoxysilane.

The amount of epoxy group-containing organic groups in all silicon atom-bonded organic groups in the epoxy group-containing organopolysiloxane may be, for example, but is not particularly limited to, 3 mol % or more, alternatively 5 mol % or more, and alternatively 10 mol % or more, and is usually 50 mol % or less, alternatively 40 mol % or less, and alternatively 30 mol % or less. The amount of the epoxy group-containing organic groups can be determined by analysis such as Fourier transform infrared spectrophotometry (FT-IR) or nuclear magnetic resonance (NMR).

The weight-average molecular weight (Mw) of the epoxy group-containing organosiloxane oligomer is not particularly limited, but can range from 500 to 3,000, and alternatively from 800 to 2,000.

As used in the present specification, the weight-average molecular weight can be determined by GPC.

The epoxy group-containing organopolysiloxane content is not particularly limited but can be an amount of from 0.01% by mass or more, alternatively 0.1% by mass or more, and still alternatively 0.3% by mass or more based on the total mass of the curable silicone composition of the present embodiments, and can also be an amount of 10% by mass or less, alternatively 5% by mass or less, and even alternatively 3% by mass or less, based on the total mass of the curable hot-melt silicone composition of the present embodiments.

A cerium-containing organopolysiloxane may be prepared, for example, by a reaction between cerium chloride or a cerium salt of a carboxylic acid and an alkali metal salt of a silanol group-containing organopolysiloxane. Thus, as used in the present specification, the term “cerium-containing organopolysiloxane” can mean a substance that is obtained by reacting a silanol group-containing organopolysiloxane and a cerium salt, where the silanol group of the organopolysiloxane and the cerium atom are chemically bonded.

Examples of cerium salts of a carboxylic acid include cerium 2-ethylhexanoate, cerium naphthenate, cerium oleate, cerium laurate, and cerium stearate. An example of a cerium chloride is cerium trichloride.

Examples of alkali metal salts of silanol group-containing organopolysiloxanes include potassium salts of diorganopolysiloxanes capped at both ends of the molecular chain with silanol groups, sodium salts of diorganopolysiloxanes capped at both ends of the molecular chain with silanol groups, potassium salts of diorganopolysiloxanes capped at one end of the molecular chain with a silanol group and capped at the other end of the molecular chain with a triorganosiloxy group, and sodium salts of diorganopolysiloxanes capped at one end of the molecular chain with a silanol group and capped at the other end of the molecular chain with a triorganosiloxy group. Moreover, examples of silicon atom-bonded groups in these organopolysiloxanes include C1-12 alkyl groups such as methyl, ethyl, propyl, isopropyl, n-butyl, isobutyl, tert-butyl, n-pentyl, neopentyl, hexyl, cyclohexyl, heptyl, octyl, nonyl, decyl, undecyl, and dodecyl groups; C6-20 aryl groups such as phenyl, tolyl, xylyl, and naphthyl groups; C7-20 aralkyl groups such as benzyl, phenethyl, and phenylpropyl groups; and any of these groups in which some or all of the hydrogen atoms are substituted with halogen atoms such as fluorine, chlorine, or bromine atoms.

The above reaction is carried out at room temperature or while heated in an alcohol such as methanol, ethanol, isopropanol, or butanol, an aromatic hydrocarbon such as toluene or xylene, an aliphatic hydrocarbon such as hexane or heptane, or an organic solvent such as mineral spirits, ligroin, or a petroleum ether. The resulting reaction product is typically treated by distilling off organic solvents or low-boiling components or filtering off sediments as needed. A dialkyl formamide, hexa-alkyl phosphoamide, or the like may also be added to facilitate the reaction. The cerium atom content of the cerium-containing organopolysiloxane thus obtained is typically within the range of 0.1 to 15% by mass.

The cerium-containing organopolysiloxane content is not particularly limited, but is typically 0.1% by mass or more, and alternatively 0.3% by mass or more, based on the total mass of the curable silicone composition of the present embodiments. The cerium-containing organopolysiloxane is also usually contained in an amount of 5% by mass or less, and alternatively 3% by mass or less, based on the total mass of the curable silicone composition.

### Other Components

Optional components can be blended into the curable silicone composition of the present disclosure, provided

that the object of the present embodiments is not thereby compromised. Examples of optional components include acetylene compounds, organic phosphorus compounds, vinyl group-containing siloxane compounds; inorganic fillers such as crushed quartz, silica, magnesium carbonate, diatomaceous earth, and inorganic fillers obtained by subjecting the surface of such inorganic fillers to hydrophobic treatment with an organosilicon compound; surface treatment agents, hydrosilylation reaction inhibitors, tackifiers, agents that confer heat resistance, agents that confer cold resistance, agents that confer flame retardance, agents that confer thixotropic properties, phosphors, and sol vents. Such optional components are usually added in an amount of 0.001 to 20% by mass of the total composition.

Hydrosilylation reaction inhibitors are components for suppressing the hydrosilylation reaction of the curable silicone composition. Examples of such curing reaction inhibitors include: alkyne alcohols such as 2-methyl-3-butyn-2-ol, 3,5-dimethyl-1-hexyn-3-ol, 2-phenyl-3-butyn-2-ol, 1-ethynyl-1-cyclohexanol, and 1-ethynyl-2-cyclohexanol; enyne compounds such as 3-methyl-3-penten-1-yne, 3,5-dimethyl-3-hexen-1-yne; alkenyl group-containing low-molecular weight siloxanes such as tetramethyltetravinylcyclotetrasiloxane and tetramethyltetrahexenylcyclotetrasiloxane; and alkynyloxysilanes such as methyl-tris(1,1-dimethylpropynyloxy) silane, vinyl-tris(1,1-dimethylpropynyloxy) silane, and methyl-tris-(3-methyl-1-butyn-3-oxy)silane. The hydrosilylation reaction inhibitor is typically selected from alkyne alcohols, and in some embodiments is 1-ethynyl-1-cyclohexanol. The reaction inhibitor is usually added in an amount of 0.001 to 5 mass % of the total composition.

The curable silicone composition according to the present embodiments can be cured to form a cured product having excellent transparency. Specifically, the cured product of the curable silicone composition of the present embodiments is highly transparent, with little yellowing, even after being heated. For example, a 2 mm thick cured product of the curable silicone composition according to the present embodiments typically has a light transmittance of 95% or more at a wavelength of 400 nm to 700 nm, even after being maintained at 150° C. for 48 hours. The light transmittance of the cured product of the curable silicone composition can be determined, for example, by analyzing the cured product using a spectrophotometer.

The curable silicone composition of the present embodiments is effectively cured for practical purposes even at low temperatures, and can be cured rapidly, with little change in shape or shrinkage while being cured, to form a cured product. The curable silicone composition of the present embodiments can be heated, for example, to a temperature of 50 to 150° C., alternatively 60 to 120° C., and alternatively 70° C. to 100° C., for 30 seconds or more, and alternatively 45 seconds or more, to form a cured product.

The curable silicone composition of the present embodiments can be prepared by mixing the various components. The method for mixing the components may be a conventionally known method but is not particularly limited; for example, the composition can be prepared using a mixing device. Examples of such mixing devices include, but are not particularly limited to, single-and twin-screw continuous mixers, double roller mixers, Ross mixers, Hobart mixers, dental mixers, planetary mixers, kneader mixers, and Henschel mixers.

### Encapsulant

The present disclosure also relates to an encapsulant for semiconductors, which comprises the curable silicone composition of the present embodiments. The present disclosure also relates to an encapsulating material that is obtained by curing the encapsulant of the present embodiments. Specifically, the encapsulating material of the present embodiments can include a cured product of the curable silicone composition of the present embodiments.

The configuration of the encapsulating material of the present embodiments is not particularly limited, but is typically dome-shaped or in the form of a sheet. Examples of semiconductors that can be encapsulated by the encapsulant, encapsulating material, or film of the present embodiments include, but are not particularly limited to, semiconductors such as SiC and GaN semiconductors, and particularly optical semiconductors such as power semiconductors and light-emitting diodes.

### Optical Semiconductor Element

The present disclosure also relates to an optical semiconductor element that has been encapsulated with the cured product of the encapsulant of the present embodiments. Specifically, the optical semiconductor element of the present disclosure comprises a cured product of the encapsulant of the present embodiments. Examples of optical semiconductor elements include light-emitting diodes (LEDs), semiconductor lasers, photodiodes, phototransistors, and light emitters and light receivers for solid-state imaging and photocouplers, where light-emitting diodes (LEDs) are particularly preferred.

Light-emitting diodes (LEDs) produce emitted light from the upper, lower, left and right sides of the optical semiconductor element, so it is undesirable for components of the light-emitting diode (LED) to absorb light, and materials having high light transmittance or high reflectance are preferred for such components. Consequently, a substrate on which the optical semiconductor element is mounted also typically comprises a material having high light transmittance or high reflectance. Examples of the substrate on which the optical semiconductor element is mounted include: conductive metals such as silver, gold and copper; non-conductive metals such as aluminum and nickel; thermoplastic resins mixed with white pigments, such as PPA and LCP; thermosetting resins containing white pigments, such as epoxy resins, BT resins, polyimide resins and silicone resins; and ceramics such as alumina and alumina nitride.

Specific embodiments of the present disclosure are presented below.

Embodiment 1: Curable silicone composition, comprising:
(A) a MQ resinous alkenyl group-containing organopolysiloxane having at least two alkenyl groups per molecule;
(B) a resinous organohydrogenpolysiloxane having at least two silicon atom-bonded hydrogen atoms per molecule;
(C) a linear organohydrogenpolysiloxane having at least two silicon atom-bonded hydrogen atoms per molecule; and
(D) a curing catalyst,
   wherein
the content of the (B) resinous organohydrogenpolysiloxane is 5% by mass or more relative to the total mass of the composition,
the total content of the (B) resinous organohydrogenpolysiloxane and the (C) linear organohydrogenpolysiloxane is 13 mass % or more relative to the total mass of the composition, and
the mass ratio of the content of the (B) resinous organohydrogenpolysiloxane relative to the content of the (C) linear organohydrogenpolysiloxane is 0.8 or more.

Embodiment 2: The curable silicone composition according to Embodiment 1, wherein the content of the (A) MQ resinous alkenyl group-containing organopolysiloxane is 30% by mass to 80% by mass.

Embodiment 3: The curable silicone composition according to Embodiment 1 or 2, wherein the (B) resinous organohydrogenpolysiloxane has a network molecular structure.

Embodiment 4: The curable silicone composition according to any of Embodiments 1 through 3, wherein the (B) resinous organohydrogenpolysiloxane comprises an MQ resinous organohydrogenpolysiloxane and/or a resinous organohydrogenpolysiloxane consisting of only M units and T units.

Embodiment 5: The curable silicone composition according to any of Embodiments 1 through 4, wherein the mass ratio of the content of the (B) resinous organohydrogenpolysiloxane relative to the content of the (C) linear organohydrogenpolysiloxane is 3 or less.

Embodiment 6: An encapsulating material for semiconductors, consisting of the curable silicone composition according to any of Embodiments 1 through 5.

Embodiment 7: An optical semiconductor device, comprising the encapsulating material according to Embodiment 6.

### EXAMPLES

The curable silicone composition of the present embodiments is described in greater detail by means of the following examples and comparative examples.

Curable silicone compositions were prepared by mixing the components in the formulations (parts by mass) shown in the tables. Below, Me denotes methyl groups, Vi denotes vinyl groups, and Ep denotes 3-glycidoxypropyl groups. The structures of the organopolysiloxane components are also shown in a simplified manner in the tables, and the functional groups other than Me in the M, D, or T unit are shown in parentheses. H/Vi indicates the molar ratio of the silicon atom-bonded hydrogen atoms (H) versus the vinyl groups (Vi) in the organopolysiloxane components. In the specification of the present application, “unit formula” indicates a chemical formula that includes a siloxane unit represented by (SiO_{x/2}) (x is an integer of 1 to 4), and “structural formula” indicates a chemical formula that does not include any such siloxane units. In the tables, “n.d.” means not determined.
Component a-1: MQ resinous alkenyl group-containing organopolysiloxane represented by average unit formula (Me₃SiO_{1/2})₄₂(ViMe₂SiO_{1/2})₇(SiO_{4/2})₅₁(OH)₄ (solid at 25° C.; number of siloxane units=55; number-average molecular weight (Mn)=3900; weight-average molecular weight (Mw)=5400)
Component a-2: Linear alkenyl group-containing organopolysiloxane represented by average structural formula ViMe₂SiO(M₂SiO)₄₀SiMe₂Vi
Component a-3: Linear alkenyl group-containing organopolysiloxane represented by average structural formula ViMe₂SiO(M₂SiO)₁₅₀SiMe₂Vi
Component a-4: MQ resinous alkenyl group-containing organopolysiloxane represented by average unit formula (Me₃SiO_{1/2})₃₉(ViMe₂SiO_{1/2})₆(SiO_{4/2})₅₅ (solid at 25° C.)
Component b-1: MQ resinous organohydrogenpolysiloxane represented by average unit formula (Me₂HSiO_{1/2})₆₂(SiO_{4/2})₃₈ (number-average molecular weight (Mn)=1300; weight-average molecular weight (Mw)=1700; network molecular structure)
Component b-2: Resinous organohydrogenpolysiloxane represented by average unit formula (Me₂HSiO_{1/2})₆₀(PhSiO_{3/2})₄₀ (number-average molecular weight (Mn)=700; weight-average molecular weight (Mw)=750; network molecular structure)
Component c-1: Linear organohydrogenpolysiloxane represented by average structural formula Me₂HSiO(Me₂SiO)₂₀SiHMe₂
Component c-2: Linear organohydrogenpolysiloxane represented by average structural formula Me₂HSiO(Ph₂SiO)SiHMe₂
Component d: Complex of platinum and divinyltetramethyldisiloxane having a platinum concentration of 3.0% by mass

Component e: Condensation reaction product of a vinyl group-containing organosiloxane oligomer capped at both ends of the molecule with silanol groups, represented by average unit formula (EpSiO_{3/2})ₐ(MeViSiO_{2/2})_{b}(Me₂SiO_{2/2})_{c}(OX)_{d} and 3-glycidoxypropyltrimethoxysilane (weight- average molecular weight: 1280)
Component f: cerium-containing dimethylpolysiloxane having a cerium content of 1.4% by mass
Component g: 1-ethynyl-1-cyclohexanol

The following assessments were made.

### Curability

The curable silicone compositions that had been obtained were analyzed using a curemeter (moving die rheometer (MIDR)) to determine the time to maximum torque from immediately after the value determined at a temperature of 90° C.

### Light Transmittance of Cured Product

The curable silicone compositions that had been obtained 3 g were heated to 90° C. for 5 minutes using a die (10 mm×50 mm×2 mm) to prepare 2 mm thick cured products. The cured products were aged for 48 hours at 150° C., and the light transmittance was then determined (450 nm wavelength) at 25° C. A light transmittance of 95% or more was rated OK.

### Cured Shrinkage

The curable silicone compositions that had been obtained 15 g were pressed for 5 minutes at 90° C. using a die (10 cm×15 cm×1 mm) to produce cured products, the cured products were cooled to ambient temperature, the dimensions were measured, and the percent change in dimensions was used as the cured shrinkage rate. A cured shrinkage rate of 1.0% or less was rated OK. This cured shrinkage corresponds to the volume shrinkage occurring when the compositions were cured.

### Die Shear Strength

Silicone compositions were used to filled circular spaces 8 mm in diameter×200 um deep in 25 mm×75 mm aluminum sheet substrates, aluminum chips were placed thereon, and the compositions were then cured for 5 minutes at 90° C. to bond the chips to the substrates. Uncured compositions were cured at 90° C. until cured. The die shear strength was determined using a bond tester (model number: SS-30WD; test mode: PH50 push; speed: 0.120 mm/sec).

TABLE 1

| | Example 1 | Example 2 | Example 3 | Example 4 | Example 5 | Example 6 | Example 7 |
|---|---|---|---|---|---|---|---|
| Component | | | | | | | |
| a-1 M₄₂M(Vi)₇Q₅₁(OH)₄ | 53 | 51.7 | 51.7 | 63 | 54.4 | 53 | 53.7 |
| a-2 M(Vi)D₄₀M(Vi) | 25.5 | 24.9 | 30.9 | 25.5 | 26.2 | 30.5 | 30.9 |
| a-3 M(VI)D₁₅₀M(Vi) | 4 | 6 | | 5 | 5 | | |
| b-1 M(H)₅₂Q₃₆ | — | 8.5 | 9.5 | 4.5 | 6.3 | 4.5 | — |
| b-2 M(H)₆₀T(Ph)₄₀ | 10.5 | 5 | | 4 | — | 4 | 7.5 |
| c-1 M(H)D₂₀M(H) | 5.8 | 5.8 | 6.8 | 3.8 | — | — | — |
| c-2 M(H)D(Ph₂)M(H) | — | — | — | 3 | 7 | 6.8 | 6.8 |
| e T(Ep)ₐD(Vi)_{b}D_{c} | 0.5 | 0.5 | 0.5 | 0.5 | 0.5 | 0.5 | 0.5 |
| f (PDMS-O)Ce | 0.5 | 0.5 | 0.5 | 0.5 | 0.5 | 0.5 | 0.5 |
| g | 0.1 | 0.1 | 0.1 | 0.1 | 0.1 | 0.1 | 0.1 |
| Total | 99.9 | 100 | 100 | 99.9 | 100 | 99.9 | 100 |
| d Pt catalyst (Pt ppm) | 9 | 9 | 9 | 9 | 9 | 9 | 9 |
| H/Vi ratio | 1 | 1.4 | 1.4 | 1.3 | 1.4 | 1.5 | 1.2 |
| Assessment | | | | | | | |
| Curing time (minutes) at 90° C. | 2 | 3 | 2 | 1.5 | 1 | 1 | 1 |
| Light transmittance after 48 hours at 150° C. | OK | OK | OK | OK | OK | OK | OK |
| Cured shrinkage | OK | OK | OK | OK | OK | OK | OK |
| Die shear strength (MPa) | 3.4 | 3.0 | 3.5 | 3.3 | 2.5 | 2.7 | 2.5 |

The results in Table 1 show that the curable silicone compositions of the present embodiments could be cured within 5 minutes even at a low temperature of 90° C., making it possible to form cured products that did not shrink much when cured, that remained highly transparent even after being aged at elevated temperatures, and that had exceptional adhesive strength.

TABLE 2

| | Comparative | Comparative | Comparative | Comparative | Comparative | Comparative | Comparative |
|---|---|---|---|---|---|---|---|
| | Example 1 | Example 2 | Example 3 | Example 4 | Example 5 | Example 5 | Example 7 |
| Component | | | | | | | |
| a-1 M₄₂M(Vi)₂Q₅₁(OH)₄ | 62.4 | 51.7 | 53.4 | 53 | 53.7 | — | — |
| a-2 M(Vi)D₄₀M(Vi) | 24.1 | 34.9 | 29.7 | 36.5 | 25.9 | 46.03 | — |
| a-3 M(Vi)D₁₅₀M(Vi) | — | — | — | — | 10 | 48.73 | 64 |
| a-4 M₃₉M(Vi)₆Q₅₅ | — | — | — | — | — | — | 30 |
| b-1 M(H)₆₂Q₃₈ | — | — | 4.5 | 4.5 | 5.3 | 4.72 | 5.5 |
| b-2 M(H)₆₀T(Ph)₄₀ | 7.5 | 4.8 | — | 4.8 | — | — | — |
| c-1 M(H)D₂₀M(H) | — | — | 7.8 | — | — | — | — |
| c-2 M(H)D(Ph₂)M(H) | 4.8 | 7.5 | 4 | — | 4 | — | — |
| e T(Ep)ₐD(Vi)_{b}D_{c} | 0.5 | 0.5 | 0.5 | 0.8 | 0.5 | 0.5 | 0.5 |
| f (PDMS-O)Ce | 0.5 | 0.5 | 0.5 | 0.5 | 0.5 | 0.5 | — |
| g | 0.1 | 0.1 | 0.1 | 0.1 | 0.1 | 0.02 | 0.02 |
| Total | 99.9 | 100 | 100.5 | 99.9 | 100 | 100 | 100 |
| d Pt catalyst (Pt: ppm) | 9 | 9 | 9 | 9 | 9 | 8 | 8 |
| H/Vi ratio | 1 | 1.1 | 1.1 | 1.1 | 1.1 | 1.3 | 1.3 |
| Assessment | | | | | | | |
| Curing time (minutes) at 90° C. | >10 | >5 | >10 | >10 | >10 | 1 | >10 |
| Light transmittance after 48 hours at 150° C. | n.d. | n.d. | n.d. | n.d. | n.d. | OK | n.d. |
| Cured shrinkage | n.d. | n.d. | n.d. | n.d. | n.d. | OK | n.d. |
| Die shear strength (MPa) | 4.5 | 2.5 | 2.8 | 2.5 | 2.5 | 0.7 | n.d. |

The results in Table 2 show that Comparative Examples 1 through 5 and 7, which were outside the scope of the present embodiments, took more than 5 minutes to be cured via heat treatment at 90° C. The cured product of Comparative Example 7 also had poor adhesive strength.

The curable silicone composition of the present embodiments can be used as an encapsulating material or coating material for optical semiconductor elements such as light-emitting diodes (LEDs).

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration in any way. Rather, the foregoing detailed description will provide those skilled in the art with a convenient road map for implementing an exemplary embodiment. It being understood that various changes may be made in the function and arrangement of elements described in an exemplary embodiment without departing from the scope as set forth in the appended claims. Moreover, all combinations of the aforementioned components, compositions, method steps, formulation steps, etc. are hereby expressly contemplated for use herein in various non-limiting embodiments even if such combinations are not expressly described in the same or similar paragraphs.

With respect to any Markush groups relied upon herein for describing particular features or aspects of various embodiments, different, special, and/or unexpected results may be obtained from each member of the respective Markush group independent from all other Markush members. Each member of a Markush group may be relied upon individually and or in combination and provides adequate support for specific embodiments within the scope of the appended claims.

Further, any ranges and subranges relied upon in describing various embodiments of the present disclosure independently and collectively fall within the scope of the appended claims, and are understood to describe and contemplate all ranges including whole and/or fractional values therein, even if such values are not expressly written herein. One of skill in the art readily recognizes that the ranges and subranges enumerated herein sufficiently describe and enable various embodiments of the present disclosure, and such ranges and subranges may be further delineated into relevant halves, thirds, quarters, fifths, and so on. As just one example, a range “of from 0.1 to 0.9” may be further delineated into a lower third, i.e., from 0.1 to 0.3, a middle third, i.e., from 0.4 to 0.6, and an upper third, i.e., from 0.7 to 0.9, which individually and collectively are within the scope of the appended claims, and may be relied upon individually and/or collectively and provide adequate support for specific embodiments within the scope of the appended claims. In addition, with respect to the language which defines or modifies a range, such as “at least,” “greater than,” “less than,” “no more than,” and the like, it is to be understood that such language includes subranges and/or an upper or lower limit. As another example, a range of “at least 10” inherently includes a subrange of from at least 10 to 35, a subrange of from at least 10 to 25, a subrange of from 25 to 35, and so on, and each subrange may be relied upon individually and/or collectively and provides adequate support for specific embodiments within the scope of the appended claims. An individual number within a disclosed range may be relied upon and provides adequate support for specific embodiments within the scope of the appended claims. For example, a range “of from 1 to 9” includes various individual integers, such as 3, as well as individual numbers including a decimal point (or fraction), such as 4.1, which may be relied upon and provide adequate support for specific embodiments within the scope of the appended claims. Lastly, it will be understood that the term “about” with regard to any of the particular numbers and ranges described herein is used to designate values within standard error, equivalent function, efficacy, final loading, etc., as understood by those of skill in the art with relevant conventional techniques and processes for formulation and/or utilizing compounds and compositions such as those described herein. As such, the term “about” may designate a value within 10, alternatively within 5, alternatively within 1, alternatively within 0.5, alternatively within 0.1, % of the enumerated value or range.

While the present disclosure has been described with respect to particular embodiments thereof, it is apparent that numerous other forms and modifications will be obvious to those skilled in the art. The appended claims and this disclosure generally should be construed to cover all such obvious forms and modifications, which are within the true scope of the present disclosure.

1. A curable silicone composition, comprising:
(A) an MQ resinous alkenyl group-containing organopolysiloxane having at least two alkenyl groups per molecule;
(B) a resinous organohydrogenpolysiloxane having at least two silicon atom-bonded hydrogen atoms per molecule;
(C) a linear organohydrogenpolysiloxane having at least two silicon atom-bonded hydrogen atoms per molecule; and
(D) a curing catalyst,
wherein
the content of the (B) resinous organohydrogenpolysiloxane is 5% by mass or more relative to the total mass of the composition,
the total content of the (B) resinous organohydrogenpolysiloxane and the (C) linear organohydrogenpolysiloxane is 13 mass % or more relative to the total mass of the composition, and
the mass ratio of the content of the (B) resinous organohydrogenpolysiloxane relative to the content of the (C) linear organohydrogenpolysiloxane is 0.8 or more.

2. The curable silicone composition of claim 1, wherein the content of the (A) MQ resinous alkenyl group-containing organopolysiloxane is from 30% to 80% by mass.

3. The curable silicone composition of claim 1, wherein the (B) resinous organohydrogenpolysiloxane has a network molecular structure.

4. The curable silicone composition of claim 1, wherein the (B) resinous organohydrogenpolysiloxane comprises an MQ resinous organohydrogenpolysiloxane and/or a resinous organohydrogenpolysiloxane consisting of only M units and T units.

5. The curable silicone composition of claim 1, wherein the mass ratio of the content of the (B) resinous organohydrogenpolysiloxane relative to the content of the (C) linear organohydrogenpolysiloxane is 3 or less.

6. An encapsulating material for semiconductors, comprising the curable silicone composition of claim 1.

7. An optical semiconductor device comprising the encapsulating material of claim 6.
